(19) United States
(12) Patent Application Publication
(10) Pub. No.: US 2010/0219419 A1
(43) Pub. Date: Sep. 2, 2010

(54) SEMICONDUCTOR ELEMENT AND METHOD FOR MANUFACTURING THE SAME

(75) Inventors: Masayuki Hata, Osaka (JP); Yasuhiko Nomura, Osaka (JP)

Correspondence Address: DITTHAVONG MORI & STEINER, P.C., 918 Prince Street, Alexandria, VA, 22314, US

(73) Assignee: SANYO ELECTRIC CO., LTD., Moriguchi-shi, Osaka (JP)

(21) Appl. No.: 12/161,358

(22) PCT Filed: Aug. 8, 2007
(86) PCT No.: PCT/JP2007/065483

§ 371 Date: Jul. 18, 2008

(30) Foreign Application Priority Data
Aug. 11, 2006 (JP) 2006-219101
Aug. 7, 2007 (JP) 2007-204962

(51) Int. Cl. H01L 33/02; H01L 21/50

(52) U.S. Cl. 257/79; 438/106; 257/E33.005; 257/E21.499

(57) ABSTRACT

Provided is a semiconductor element which can suppress deterioration of element characteristics even when a semiconductor element section includes a plurality of directions having different thermal expansion coefficients within an in-plane direction. A semiconductor laser element (the semiconductor element) is provided with the semiconductor element section, which includes a direction of [1-100] and a direction of [0001] having different thermal expansion coefficients within the in-plane direction of a main surface, and a sub-mount, which includes an arrow (E) direction and an arrow (F) direction having different thermal expansion coefficients within the in-plane direction of the main surface. The semiconductor element section is bonded on the sub-mount so that the direction [1-100] of the semiconductor element section is close to the side of the arrow (E) direction than the arrow (F) direction of the sub-mount.

### TECHNICAL FIELD

The present invention relates to a semiconductor element and a method for manufacturing the same, and more particularly, it relates to a semiconductor element comprising a semiconductor element section including a plurality of directions having different thermal expansion coefficients in the in-plane directions of the principal surface and a method for manufacturing the same.

### BACKGROUND ART

In general, Japanese Patent Laying-Open No. 2001-7394 discloses a semiconductor light-emitting element (semiconductor element) comprising a GaN-based semiconductor multilayer structure (semiconductor element section) including a plurality of directions having different thermal expansion coefficients in the in-plane directions of the principal surface.

In the conventional semiconductor light-emitting element disclosed in Japanese Patent Laying-Open No. 2001-7394, the GaN-based semiconductor multilayer structure having a (1-100) plane as the principal surface is formed by stacking the GaN-based semiconductor multilayer structure on a single-crystalline substrate having a (1-100) plane as the principal surface. It is known that the thermal expansion coefficient of a wurtzite GaN-based semiconductor multilayer structure comprising a principal surface other than the (0001) plane has anisotropy in the in-plane directions of the principal surface. In the in-plane directions of the (1-100) plane, for example, the thermal expansion coefficient in a c-axis direction corresponding to the [0001] direction and the thermal expansion coefficient in an a-axis direction corresponding to the [11-20] direction are different from each other. The GaN-based semiconductor multilayer structure is bonded to a base having isotropic thermal expansion coefficients in the in-plane directions of the principal surface.

In the semiconductor light-emitting element disclosed in Japanese Patent Laying-Open No. 2001-7394, however, the GaN-based semiconductor multilayer structure having the anisotropic thermal expansion coefficients in the in-plane directions of the principal surface is bonded to the base having the isotropic thermal expansion coefficients in the in-plane directions of the principal surface, and hence it is disadvantageously difficult to reduce the difference between the thermal expansion coefficients of the base and the GaN-based semiconductor multilayer structure as to the respective in-plane directions of the bonded surfaces. Therefore, the GaN-based semiconductor multilayer structure is strained due to the difference between a temperature for bonding the GaN-based semiconductor multilayer structure to the base and a temperature in operation of the semiconductor light-emitting element, and hence the element characteristics of the semiconductor light-emitting element are disadvantageously degraded.

### DISCLOSURE OF THE INVENTION

The present invention has been proposed in order to solve the aforementioned problems, and an object of the present invention is to provide a semiconductor element capable of suppressing degradation of element characteristics also when a semiconductor element section includes a plurality of directions having different thermal expansion coefficients in the in-plane directions and a method for manufacturing the same.

A semiconductor element according to a first aspect of the present invention comprises a semiconductor element section having a first surface and including a plurality of directions having different thermal expansion coefficients in the in-plane directions of the first surface and a base having a second surface and including a plurality of directions having different thermal expansion coefficients in the in-plane directions of the second surface, with the first surface of the semiconductor element section bonded to the second surface, while the semiconductor element section is so bonded to the base that the direction having the largest thermal expansion coefficient in the first surface of the semiconductor element section is closer to the side of the direction having the largest thermal expansion coefficient than the direction having the smallest thermal expansion coefficient in the second surface of the base.

As hereinabove described, the semiconductor element according to the first aspect of the present invention is provided with the semiconductor element section including the plurality of directions having the different thermal expansion coefficients in the in-plane directions of the first surface and the base including the plurality of directions having the different thermal expansion coefficients in the in-plane directions of the second surface and so formed as to bond the semiconductor element section to the base so that the direction having the largest thermal expansion coefficient in the first surface of the semiconductor element section is closer to the side of the direction having the largest thermal expansion coefficient than the direction having the smallest thermal expansion coefficient in the second surface of the base, so that the difference between the thermal expansion coefficients can be reduced in the respective in-plane directions of the plane where the first surface of the semiconductor element section and the second surface of the base are bonded to each other, whereby the first surface of the semiconductor element section can be inhibited from occurrence of strain resulting from the difference between a temperature for bonding the semiconductor element section to the base and a temperature in operation of the semiconductor element. Consequently, degradation of the element characteristics of the semiconductor element can be suppressed also when the semiconductor element section includes the plurality of directions having the different thermal expansion coefficients in the in-plane directions of the first surface.

In the aforementioned semiconductor element according to the first aspect, the direction having the largest thermal expansion coefficient in the in-plane directions of the first surface of the semiconductor element section preferably substantially coincides with the direction having the largest thermal expansion coefficient in the in-plane directions of the second surface of the base.

When the largest thermal expansion coefficient and the smallest thermal expansion coefficient in the in-plane directions of the first surface of the semiconductor element section are α_{EL} and α_{ES} respectively and the largest thermal expansion coefficient and the smallest thermal expansion coefficient in the in-plane directions of the second surface of the base are α_{SL} and as α_{SS} respectively in the aforementioned semiconductor element according to the first aspect, at least one relation of α_{SL}≧α_{EL}>α_{SS} or α_{SL}>α_{ES}≧α_{SS} or α_{EL}≧α_{SL}>α_{ES} or α_{EL}>α_{SS}≧α_{ES} preferably holds between the thermal expansion coefficients in the respective directions of the base and the semiconductor element section. According to this structure, the difference between the thermal expansion coefficients corresponding to the respective directions of the first surface of the semiconductor element section and the second surface of the base can be further reduced.

When the largest thermal expansion coefficient and the smallest thermal expansion coefficient in the in-plane directions of the first surface of the semiconductor element section are α_{EL} and α_{ES} respectively and the largest thermal expansion coefficient and the smallest thermal expansion coefficient in the in-plane directions of the second surface of the base are α_{SL} and α_{SS} respectively in the aforementioned semiconductor element according to the first aspect, the relation of α_{SL}>α_{SS}≧α_{EL}>α_{ES} or α_{EL}>α_{ES}≧α_{SL}>α_{SS} preferably holds between the thermal expansion coefficients in the respective directions of the base and the semiconductor element section. Also according to this structure, the difference between the thermal expansion coefficients corresponding to the respective directions of the first surface of the semiconductor element section and the second surface of the base can be reduced.

When the largest thermal expansion coefficient and the smallest thermal expansion coefficient in the first surface of the semiconductor element section are α_{EL} and α_{ES} respectively and the largest thermal expansion coefficient and the smallest thermal expansion coefficient in the second surface of the base are α_{SL} and α_{SS} respectively in the aforementioned semiconductor element according to the first aspect, the first surface of the semiconductor element section is preferably rectangularly formed so that the thermal expansion coefficient in the direction along the long side is α_{ES} if |α_{SL}−α_{EL}|>|α_{SS}−α_{ES}|, and the first surface of the semiconductor element section is preferably rectangularly formed so that the thermal expansion coefficient in the direction along the long side is α_{EL} if |α_{SL}−α_{EL}|<|αₛₛ−α_{ES}|. According to this structure, a semiconductor element section having a rectangular shape coinciding the directions along the long side and the short side of the first surface with the base part can be formed on the basis of the magnitude relation of the difference between the thermal expansion coefficients in the respective directions of the semiconductor element section and the base as shown in the above relational expressions, whereby the direction along the long side easily causing strain as compared with the direction along the short side of the semiconductor element section can be effectively inhibited from occurrence of strain.

In the aforementioned semiconductor element according to the first aspect, the appearance of the semiconductor element section is preferably so formed that the direction having the largest thermal expansion coefficient in the in-plane directions of the first surface of the semiconductor element section and the direction having the smallest thermal expansion coefficient in the in-plane directions of the first surface of the semiconductor element section can be distinguished from each other.

In the aforementioned semiconductor element according to the first aspect, the shape of the first surface of the semiconductor element section is preferably substantially rectangularly formed. According to this structure, the direction having the largest thermal expansion coefficient in the in-plane directions of the first surface of the semiconductor element section and the direction having the smallest thermal expansion coefficient can be easily distinguished from each other.

In the aforementioned semiconductor element according to the first aspect, the appearance of the semiconductor element section is preferably so formed that the direction having the largest thermal expansion coefficient in the in-plane directions of the second surface of the base and the direction having the smallest thermal expansion coefficient in the in-plane directions of the second surface of the base can be distinguished from each other.

In the aforementioned semiconductor element according to the first aspect, the semiconductor element section preferably includes a semiconductor layer having the first surface and having a hexagonal structure or a wurtzite structure, and the first surface is preferably substantially a (H, K, −H−K, 0) plane, where at least either one of H and K is a nonzero integer.

The aforementioned semiconductor element according to the first aspect preferably further comprises a bonding layer for bonding the second surface of the base and the first surface of the semiconductor element section to each other.

In this case, the base and the bonding layer are preferably both electrically conductive. According to this structure, the second surface of the electrically conductive base and the first surface of the semiconductor element section can be bonded to each other through the electrically conductive bonding layer, whereby the semiconductor element section and the base can be easily electrically connected with each other.

In the aforementioned structure comprising the bonding layer, the bonding layer is preferably provided on a region separated from a cavity facet of the semiconductor element section at a prescribed distance in the extensional direction of a cavity. According to this structure, a region where the base and the semiconductor element section are separated from each other can be formed in the vicinity of an end of the cavity facet of the semiconductor element section closer to the base by a region provided with no bonding layer. Thus, the semiconductor element section can be cleaved without receiving influence by cleavability on the base part, dissimilarly to a case where the bonding layer and the base are provided adjacently to the end of the cavity facet closer to the base. Also when a cleavage plane on the base part has no cleavability, therefore, planarity of a cleavage plane of the semiconductor element section can be improved.

The aforementioned semiconductor element according to the first aspect is preferably so formed that the Young's modulus of the base is smaller than the Young's modulus of the semiconductor element section. According to this structure, the Young's modulus of the base is smaller than the Young's modulus of the semiconductor element section, whereby the first surface of the semiconductor element section can be further inhibited from occurrence of strain.

In the aforementioned semiconductor element according to the first aspect, the semiconductor element section is preferably a semiconductor light-emitting element section including an emission layer. According to this structure, the semiconductor element section is bonded to the base part in a state inhibited from occurrence of strain on the first surface, whereby degradation of the element characteristics of the light-emitting element section can be easily suppressed.

In the aforementioned semiconductor element according to the first aspect, the base is preferably a submount.

A method for manufacturing a semiconductor element according to a second aspect of the present invention comprises steps of forming a semiconductor element section having a first surface and including a plurality of directions having different thermal expansion coefficients in the in-plane directions of the first surface and bonding the first surface of the semiconductor element section to a second surface of a base having the second surface and including a plurality of directions having different thermal expansion coefficients in the in-plane directions of the second surface so that the direction having the largest thermal expansion coefficient in the first surface is closer to the side of the direction having the largest thermal expansion coefficient than the direction having the smallest thermal expansion coefficient in the second surface.

As hereinabove described, the method for manufacturing a semiconductor element according to the second aspect of the present invention is so formed as to bond the semiconductor element section to the base including the plurality of directions having the different thermal expansion coefficients in the in-plane directions of the second surface so that the direction having the largest thermal expansion coefficient in the first surface is closer to the side of the direction having the largest thermal expansion coefficient than the direction having the smallest thermal expansion coefficient in the second surface, so that the difference between the thermal expansion coefficients can be reduced in the respective in-plane directions of the plane where the first surface of the semiconductor element section and the second surface of the base are bonded to each other, whereby the first surface of the semiconductor element section can be inhibited from occurrence of strain resulting from the difference between a temperature for bonding the semiconductor element section to the base and a temperature in operation of the semiconductor element. Consequently, degradation of the element characteristics of the semiconductor element can be suppressed also when the semiconductor element section includes the plurality of directions having the different thermal expansion coefficients in the in-plane directions of the first surface.

In the aforementioned method for manufacturing a semiconductor element according to the second aspect, the step of forming the semiconductor element section preferably includes a step of growing the semiconductor element section including the plurality of directions having the different thermal expansion coefficients in the in-plane directions of the first surface on the surface of a growth substrate including a plurality of directions having different thermal expansion coefficients in the in-plane directions.

In the aforementioned method for manufacturing a semiconductor element according to the second aspect, the step of bonding the first surface of the semiconductor element section to the second surface of the base preferably includes a step of bonding a side of the semiconductor element section formed on a growth substrate in the step of forming the semiconductor element section to the base to be opposed thereto, the method preferably further comprises a step of removing the growth substrate after the step of bonding the first surface of the semiconductor element section to the second surface of the base, and the base is preferably a support substrate.

When the largest thermal expansion coefficient and the smallest thermal expansion coefficient in the first surface of the semiconductor element section are α_{EL} and α_{ES} respectively and the largest thermal expansion coefficient and the smallest thermal expansion coefficient in the second surface of the base are α_{SL} and α_{SS} respectively in the aforementioned method for manufacturing a semiconductor element according to the second aspect, the step of forming the semiconductor element section having the first surface preferably includes a step of rectangularly forming the first surface of the semiconductor element section so that the thermal expansion coefficient in the direction along the long side is α_{ES} if |α_{SL}−α_{EL}|>|α_{SS}−α_{ES}| and rectangularly forming the first surface of the semiconductor element section so that the thermal expansion coefficient in the direction along the long side is α_{EL} if |α_{SL}−α_{EL}|<|α_{SS}−α_{ES}|. According to this structure, a semiconductor element section having a rectangular shape coinciding the directions along the long side and the short side of the first surface with the base part can be formed on the basis of the magnitude relation of the difference between the thermal expansion coefficients in the respective directions of the semiconductor element section and the base as shown in the above relational expressions, whereby a semiconductor element in which the direction along the long side easily causing strain as compared with the direction along the short side of the semiconductor element section is effectively inhibited from occurrence of strain can be obtained.

When the largest thermal expansion coefficient and the smallest thermal expansion coefficient in the first surface of the semiconductor element section are α_{EL} and α_{ES} respectively and the largest thermal expansion coefficient and the smallest thermal expansion coefficient in the second surface of the base are α_{SL} and α_{SS} respectively in the aforementioned method for manufacturing a semiconductor element according to the second aspect, the step of bonding the first surface of the semiconductor element section to the second surface of the base preferably includes a step of bonding the surfaces to each other while coinciding the directions within the second surface of the base and the first surface of the semiconductor element section with each other so that at least one relation of α_{SL}≧α_{EL}>α_{SS} or α_{SL}>α_{ES}≧α_{SS} or α_{EL}≧α_{SL}>α_{ES} or α_{EL}>α_{SS}≧α_{ES} holds between the thermal expansion coefficients in the respective directions of the base and the semiconductor element section. According to this structure, the difference between the thermal expansion coefficients corresponding to the respective directions of the first surface of the semiconductor element section and the second surface of the base can be further reduced.

### BRIEF DESCRIPTION OF THE DRAWINGS

FIG. 1 A plan view for illustrating the concept of the present invention.

FIG. 2 A sectional view taken along the line 1000-1000 in FIG. 1.

FIG. 3 A plan view showing the structure of a semiconductor laser element according to a first embodiment of the present invention.

FIG. 4 A sectional view taken along the line 2000-2000 in FIG. 3.

FIG. 5 A sectional view taken along the line 3000-3000 in FIG. 3.

FIG. 6 A sectional view showing the structure of an emission layer of the semiconductor laser element according to the embodiment shown in FIG. 3.

FIG. 7 A sectional view for illustrating a manufacturing process for the semiconductor laser element according to the first embodiment of the present invention.

FIG. 8 A sectional view for illustrating the manufacturing process for the semiconductor laser element according to the first embodiment of the present invention.

FIG. 9 A sectional view for illustrating the manufacturing process for the semiconductor laser element according to the first embodiment of the present invention.

FIG. 10 A sectional view for illustrating the manufacturing process for the semiconductor laser element according to the first embodiment of the present invention.

FIG. 11 A sectional view for illustrating the manufacturing process for the semiconductor laser element according to the first embodiment of the present invention.

FIG. 12 A plan view for illustrating the manufacturing process for the semiconductor laser element according to the first embodiment of the present invention.

FIG. 13 A sectional view for illustrating the manufacturing process for the semiconductor laser element according to the first embodiment of the present invention.

FIG. 14 A sectional view for illustrating the manufacturing process for the semiconductor laser element according to the first embodiment of the present invention.

FIG. 15 A sectional view for illustrating the manufacturing process for the semiconductor laser element according to the first embodiment of the present invention.

FIG. 16 A plan view showing the structure of a GaN-based semiconductor laser element according to a second embodiment of the present invention.

FIG. 17 A sectional view taken along the line 4000-4000 in FIG. 16.

FIG. 18 A plan view showing the structure of a light-emitting diode element according to a third embodiment of the present invention.

FIG. 19 A plan view showing the structure of the light-emitting diode element according to the third embodiment of the present invention.

FIG. 20 A plan view showing the structure of a GaN-based semiconductor laser element according to a fourth embodiment of the present invention.

FIG. 21 A sectional view taken along the line 5000-5000 in FIG. 20.

### BEST MODES FOR CARRYING OUT THE INVENTION

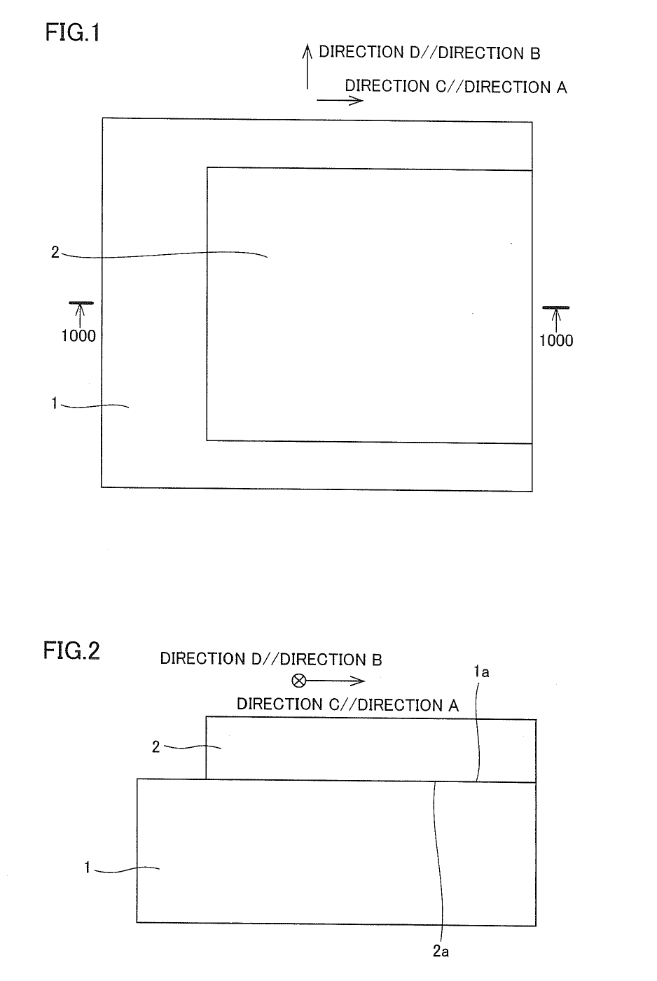

With reference to FIGS. 1 and 2, the concept of the present invention is described before describing specific embodiments of the present invention.

The semiconductor element according to the present invention comprises a base 1 and a semiconductor element section 2 bonded to the base 1, as shown in FIGS. 1 and 2.

The base 1 of the semiconductor element may be a submount, or may be a support substrate. The base 1 includes a plurality of directions having different thermal expansion coefficients in the in-plane directions of a principal surface 1a bonded to the semiconductor element section 2. More specifically, the base 1 has the largest thermal expansion coefficient α_{SL} along arrow A, and has the smallest thermal expansion coefficient α_{SS} along arrow B, as shown in FIG. 2, for example. The principal surface 1a is an example of the “second surface” in the present invention.

As the base 1 having different thermal expansion coefficients varying with the in-plane directions, a material having an orthorhombic, tetragonal, hexagonal, rhombohedral, monoclinic or triclinic crystal structure other than a cubic crystal structure can be employed as a single-crystalline material. Such a material having a crystal structure other than the cubic crystal structure generally has anisotropy in thermal expansion coefficients due to crystal symmetry. Such a material having a crystal structure other than the cubic crystal structure is so worked that anisotropy of the thermal expansion coefficients appears in the in-plane directions of the principal surface 1a. For example, a material having a tetragonal or hexagonal crystal structure is so worked that a plane other than the plane perpendicular to the c-axis forms the principal surface 1a.

As the single-crystalline material, α-sic having a hexagonal or rhombohedral structure, a nitride-based semiconductor such as GaN or AlN having a wurtzite structure, or hexagonal ZrB₂ or HfB₂ can be employed, for example. The hexagonal single-crystalline material is so formed that the principal surface 1a is a (H, K, −H−K, L) plane such as the {1-100} plane, the {11-20} plane, the {11-22} plane or the {1-101} plane, for example, other than the (0001) plane.

When employing a material other than the single-crystalline material as the base 1 having thermal expansion coefficients varying with the in-plane directions, a material having anisotropy in thermal expansion coefficients by orientation of crystals having anisotropy in thermal expansion coefficients may be employed. Such a material includes polycrystalline AlN in which c-axis directions of AlN particles are oriented, for example, or a composite material of carbon and metal consisting of a graphite particle sintered body impregnated with metal. Such a material is so formed that a direction where particles are oriented and a direction perpendicular to the direction where the particles are oriented appear in the plane of the principal surface 1a.

The appearance of the principal surface 1a of the base 1 is preferably so formed that the direction having the largest thermal expansion coefficient and the direction having the smallest thermal expansion coefficient can be distinguished from each other in the in-plane directions of the principal surface 1a. For example, a mark allowing recognition of the direction having the largest thermal expansion coefficient may be formed on the surface of the base 1, while the direction having the largest thermal expansion coefficient may be rendered recognizable by the shape or arrangement of an electrode when the electrode is formed on the base 1. For example, the electrode may be formed in a rectangular shape of twofold rotational symmetry coinciding the direction along the long side or the short side with the direction having the largest thermal expansion coefficient so that the direction having the largest thermal expansion coefficient can be recognized. The twofold rotational symmetry denotes that there is a twofold symmetrical rotational position during rotation from 0° to 360°, and the rectangular shape corresponds to this twofold rotational symmetry. In this case, a shape other than the rectangular shape may also be employed if the same is a shape having low symmetry such as twofold or onefold symmetry. Alternatively, the appearance of the base 1 may be so formed that the direction having the largest thermal expansion coefficient can be recognized. In other words, the principal surface 1a of the base 1 may be formed in a rectangular shape of twofold rotational symmetry coinciding the direction along the long side or the short side with the direction having the largest thermal expansion coefficient if the base 1 is a submount, while an orientation flat may be formed on a support substrate if the base 1 is the support substrate.

To the base 1, the semiconductor element section 2 may be bonded through a bonding layer, or the semiconductor element section 2 may be directly bonded.

In the semiconductor element section 2 of the semiconductor element, the principal surface 2a bonded to the base 1 has anisotropy in thermal expansion coefficients in the in-plane directions. For example, the principal surface 2a has the largest thermal expansion coefficient α_{EL} along arrow C and has the smallest thermal expansion coefficient α_{ES} along arrow D, as shown in FIG. 2. The semiconductor element section 2 contains a semiconductor having an orthorhombic, tetragonal, hexagonal, rhombohedral, monoclinic or triclinic crystal structure other than a cubic crystal structure. In this semiconductor, the plane orientation of the principal surface 2a is so selected that anisotropy in thermal expansion coefficients appears in the in-plane directions of the principal surface 2a. When the semiconductor element section 2 consists of a hexagonal semiconductor, for example, the principal surface 2a is so formed as to be a (H, K, −H−K, L) plane such as the {1-100} plane, the {11-20} plane, the {11-22} plane or the {1-101} plane, for example, other than the (0001) plane. The principal surface 2a is an example of the “first surface” in the present invention.

As the semiconductor of the semiconductor element section 2, a nitride-based semiconductor consisting of GaN, AlN, InN, BN or TlN having a wurtzite structure or mixed crystals of these, α-SiC or ZnO or ZnS having a wurtzite structure can be employed, for example. When the semiconductor element section 2 is so prepared from GaN, InN or GaInN, for example, that principal surface 2a is the (H, K, −H−K, L) plane, the direction having the largest thermal expansion coefficient in the plane is the [K, −H, H−K, 0] direction. When the semiconductor element section 2 is so prepared from GaN, InN or GaInN that the principal surface 2a is the (H, K, −H−K, 0) plane, on the other hand, the direction having the largest thermal expansion coefficient in the plane is the [K, −H, H−K, 0] direction, and the direction having the smallest thermal expansion coefficient is the [0001] direction.

The appearance of the principal surface 2a of the semiconductor element section 2 is preferably so formed that the direction having the largest thermal expansion coefficient and the direction having the smallest thermal expansion coefficient can be distinguished from each other in the in-plane directions of the principal surface 2a before the same is bonded to the base 1. For example, a mark allowing recognition of the direction having the largest thermal expansion coefficient may be formed on the surface of the semiconductor element section 2, while the direction having the largest thermal expansion coefficient may be rendered recognizable by the shape or arrangement of an electrode when the electrode is formed on the semiconductor element section 2. For example, the electrode may be formed in a rectangular shape of twofold rotational symmetry coinciding the direction along the long side or the short side with the direction having the largest thermal expansion coefficient. Alternatively, the appearance of the semiconductor element section 2 may be so formed that the direction having the largest thermal expansion coefficient can be recognized. In other words, the principal surface 2a of the semiconductor element section 2 may be formed in a rectangular shape of twofold rotational symmetry coinciding the direction along the long side or the short side with the direction having the largest thermal expansion coefficient. When the semiconductor element is a semiconductor laser element of an end emission type, the direction having the largest thermal expansion coefficient may be rendered recognizable by the extensional direction of an optical waveguide of the semiconductor laser element.

The semiconductor element section 2 may include a substrate. In a p-n junction semiconductor element, the semiconductor element section 2 may include a multilayer structure of a p-type layer and an n-type layer. In a p-n junction semiconductor light-emitting element, the semiconductor element section 2 may include an emission layer between a p-type layer and an n-type layer, and the emission layer may be undoped. The emission layer may have a single-layer or single quantum well (SQW) structure or a multiple quantum well (MWQ) structure.

Strain may be applied to the emission layer. In this case, a piezoelectric field caused in the emission layer can be reduced when the emission layer has a wurtzite structure and is so formed that the principal surface of the emission layer is a (H, K, −H−K, L) plane such as the {1-100} plane, the {11-20} plane, the {11-22} plane or the {1-101} plane, for example, other than the (0001) plane. Therefore, luminous efficiency can be improved. Further, GaInN can be employed as the material for the emission layer.

Each of the p-type layer and the n-type layer may include a cladding layer or the like having a larger band gap than an active layer. In the case of the semiconductor laser element, an optical guide layer having a band gap smaller than the band gap of the cladding layer and larger than the band gap of the active layer may be formed between the cladding layer and the active layer. A contact layer may be formed on the cladding layer opposite to the active layer. The contact layer preferably has a smaller band gap than the cladding layer. GaN or AlGaN can be employed as the material for the cladding layer.

According to the present invention, the semiconductor element section 2 is bonded to the base 1 so that the direction having the largest thermal expansion coefficient (α_{EL}) in the principal surface 2a of the semiconductor element section 2 is closer to the direction having the largest thermal expansion coefficient (α_{SL}) in the principal surface 1a of the base 1 than the direction having the smallest thermal expansion coefficient (α_{SS}). More preferably, the semiconductor element section 2 is bonded to the base 1 so that the direction (along arrow C) having the largest thermal expansion coefficient (α_{EL}) in the principal surface 2a of the semiconductor element section 2 substantially coincides with the direction (along arrow A) having the largest thermal expansion coefficient (α_{SL}) in the principal surface 1a of the base 1, as shown in FIG. 2.

According to the present invention, at least one relation of α_{SL}≧α_{EL}>α_{SS} or α_{SL}>α_{ES}≧α_{SS} or α_{EL}≧α_{SL}>α_{ES} or α_{EL}>α_{SS}≧α_{ES} preferably holds between the thermal expansion coefficients of the respective directions of the base 1 and the semiconductor element section 2, and the difference between the thermal expansion coefficients in the planes (the principal surface 1a and the principal surface 2a) of the base 1 and the semiconductor element section 2 can be further reduced in this case. However, the semiconductor element has the effects of the present invention also when the thermal expansion coefficients in the respective directions of the base 1 and the semiconductor element section 2 are α_{SL}>α_{SS}≧α_{EL}>α_{ES} or α_{EL}>α_{ES}≧α_{SL}>α_{SS}.

In addition to the above, the semiconductor element section 2 is preferably rectangularly formed so that the thermal expansion coefficient in the direction along the long side is α_{ES} if |α_{SL}−α_{EL1}>|αₛₛ−α_{ES}| or the semiconductor element section 2 is preferably rectangularly formed so that the thermal expansion coefficient in the direction along the long side is α_{EL} if |α_{SL}−α_{EL}|<|α_{SS}−α_{ES}|, when the principal surface 2a of the semiconductor element section 2 is rectangularly formed. According to this structure, the direction along the long side easily causing strain as compared with the direction along the short side of the semiconductor element section can be effectively inhibited from occurrence of strain.

Embodiments of the present invention embodying the aforementioned concept of the present invention are now described with reference to the drawings.

### First Embodiment

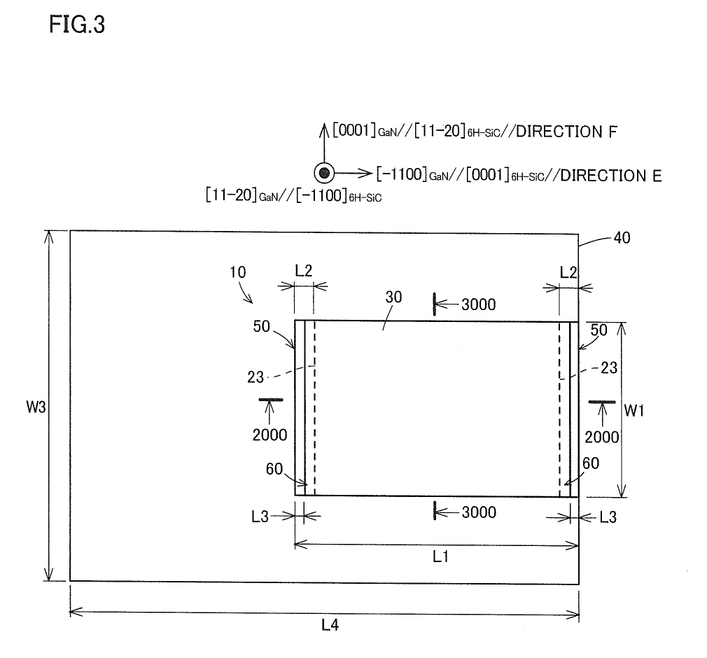

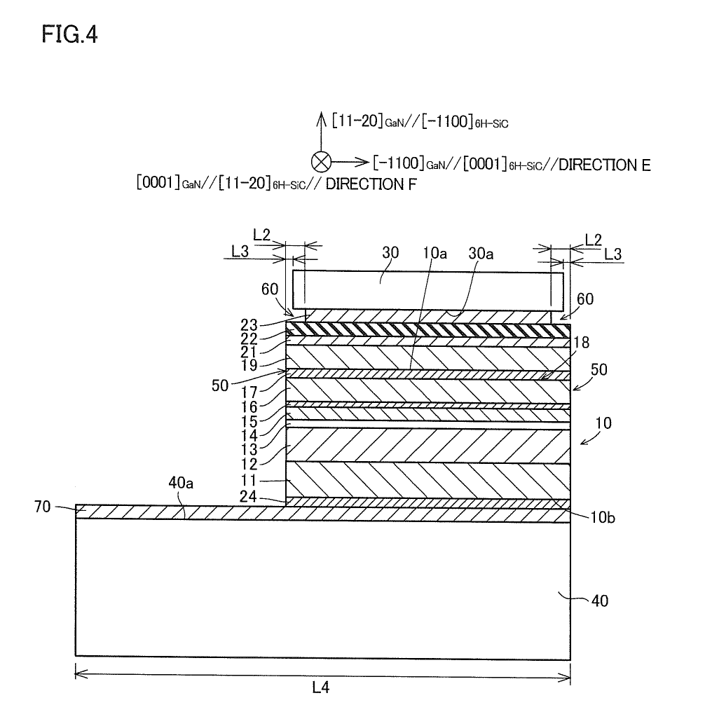

The structure of a semiconductor laser element according to a first embodiment is described with reference to FIGS. 3 to 6. The first embodiment is described with reference to a case applying the present invention to a semiconductor laser element which is an exemplary semiconductor element. The oscillation wavelength of the semiconductor laser element according to the first embodiment is about 410 nm, and a laser beam is polarized in a TM mode. Referring to FIGS. 3 to 5, crystal orientations described before a subscript GaN are the crystal orientations of a semiconductor element section 10, and crystal orientations described before a subscript 6H—SiC are the crystal orientations of a support substrate 30. FIGS. 3 and 4 show the crystal orientations of the semiconductor element section 10 omitting the misoriention angle of the semiconductor element section 10.

The semiconductor laser element according to the first embodiment comprises the semiconductor element section 10, the support substrate 30 and a submount 40 serving as a heat radiation member, as shown in FIGS. 3 to 5. The support substrate 30 and the submount 40 are examples of the “base” in the present invention.

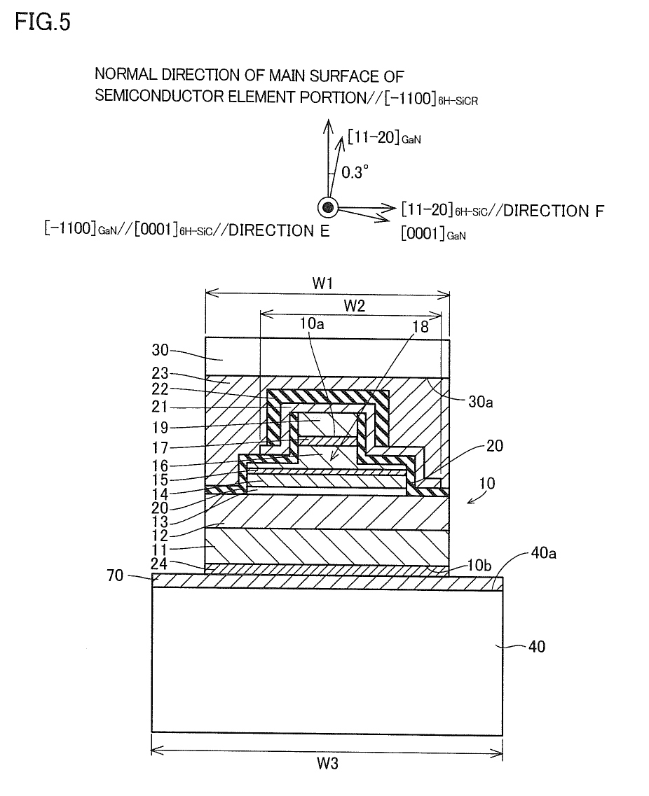

According to the first embodiment, the semiconductor element section 10 is consists of a nitride-based semiconductor having a wurtzite structure. This semiconductor element section 10 has a first principal surface (overall upper surface of the semiconductor element section 10 closer to a p-type contact layer 17) 10a and a second principal surface (back surface of an n-type contact layer 11) 10b substantially having (11-20) planes misoriented (inclined) by about 0.3° in the [000-1] direction, as shown in FIG. 5. A pair of cavity facets 50 consisting of cleavage planes are formed on the semiconductor element section 10, as shown in FIGS. 3 and 4. These cavity facets 50 are constituted of (1-100) and (−1100) planes. A dielectric multilayer film having reflectivity of about 5% is formed on the cavity facet 50 provided on the side of a laser beam emission surface, while a dielectric multilayer film having reflectivity of about 95% is formed on the opposite cavity facet 50. The length (cavity length) L1 of the semiconductor element section 10 is about 600 μm, and the width W1 is about 400 μm. The semiconductor element section 10 is bonded to the support substrate 30 through a solder layer 23 described later. The first principal surface 10a and the second principal surface 10b are examples of the “first surface” in the present invention, and the solder layer 23 is an example of the “bonding layer” in the present invention.

The semiconductor element section 10 includes the n-type contact layer 11 of GaN having a thickness of about 5 μm, as shown in FIGS. 4 and 5. An n-type cladding layer 12 having a thickness of about 40 nm and consisting of Al_{0.07}Ga_{0.93}N doped with Si is formed on the upper surface of the n-type contact layer 11. An emission layer 13 having a width of about 4.5 μm smaller than the width W1 (see FIG. 5) of the semiconductor element section 10 is formed on the upper surface of the n-type cladding layer 12.

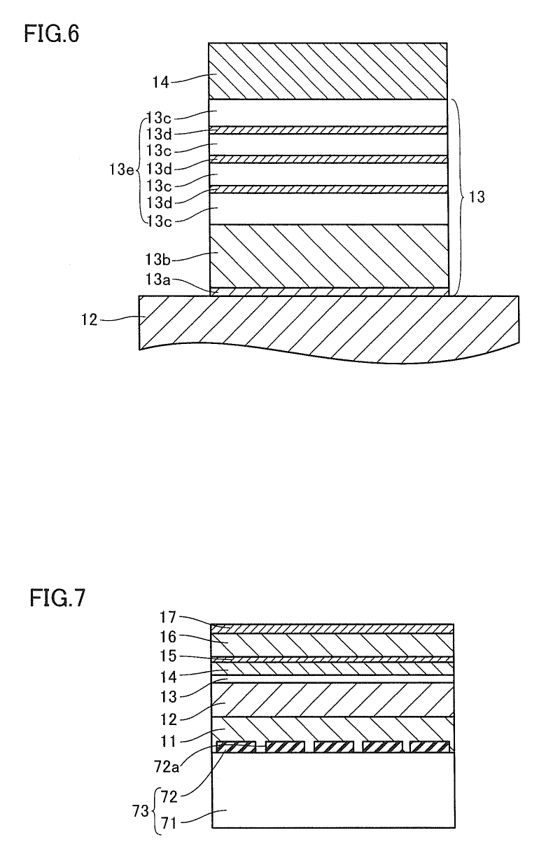

In this emission layer 13, an n-type carrier blocking layer 13a having a thickness of about 5 nm and consisting of Al_{0.16}Ga_{0.84}N doped with Si is formed on the upper surface of the n-type cladding layer 12, as shown in FIG. 6. An n-type optical guide layer 13b having a thickness of about 100 nm and consisting of GaN doped with Si is formed on the upper surface of the n-type carrier blocking layer 13a. A multiple quantum well (MQW) active layer 13e in which four barrier layers 13c having a thickness of about 20 nm and consisting of undoped In_{0.02}Ga_{0.98}N and three quantum well layers 13d having a thickness of about 3 nm and consisting of undoped In_{0.15}Ga_{0.85}N are alternately stacked is formed on the upper surface of the n-type optical guide layer 13b.

A p-type optical guide layer 14 having a thickness of about 100 nm and consisting of GaN doped with Mg is formed on the upper surface of the emission layer 13, as shown in FIGS. 4 and 5. A p-type cap layer 15 having a thickness of about 20 nm and consisting of Al_{0.16}Ga_{0.84}N doped with Mg is formed on the upper surface of the p-type optical guide layer 14. A p-type cladding layer 16 having a projecting portion and a planar portion other than the projecting portion and consisting of Al_{0.07}Ga_{0.93}N doped with Mg is formed on the upper surface of the p-type cap layer 15. The thickness of the projecting portion of this p-type cladding layer 16 is about 400 nm, and the thickness of the planar portion of the p-type cladding layer 16 other than the projecting portion is about 80 nm. The p-type contact layer 17 having a thickness of about 10 nm and consisting of In_{0.02}Ga_{0.98}N doped with Mg is formed on the upper surface of the projecting portion of the p-type cladding layer 16. Thus, the projecting portion of the p-type cladding layer 16 and the p-type contact layer 17 form a ridge portion 18 serving as a current path. This ridge portion 18 has a width of about 1.5 μm, and has a height of about 380 nm. The ridge portion 18 is so formed as to extend in the [1-100] direction.

A p-side ohmic electrode 19 constituted of a Pt layer having a thickness of about 5 nm, a Pd layer having a thickness of about 100 nm and an Au layer having a thickness of about 150 nm from the lower layer toward the upper layer is formed on the upper surface of the p-type contact layer 17. An insulating film 20 of SiN having a thickness of about 250 nm is formed on the upper surfaces of the n-type cladding layer 12 and the planar portion of the p-type cladding layer 16 other than the projecting portion and the side surfaces of the emission layer 13, the p-type optical guide layer 14, the p-type cap layer 15, the p-type cladding layer 16, the p-type contact layer 17 and the p-side ohmic electrode 19. A p-side pad electrode 21 constituted of a Ti layer having a thickness of about 100 nm, a Pd layer having a thickness of about 100 nm and an Au layer having a thickness of about 3 μm from the lower layer toward the upper layer is formed on the upper surface of the insulating film 20 and the upper surface of the p-side ohmic electrode 19. This p-side pad electrode 21 has a width W2 (see FIG. 5) of about 125 μm. An insulating film 22 of SiO₂ having a thickness of about 100 nm is formed on the upper surface of the p-side pad electrode 21. The electrically conductive solder layer 23 of AuSn is formed on the upper surface of the insulating film 20, to cover the p-side pad electrode 21 and the insulating film 22. The insulating film 22 has a function of suppressing reaction between the solder layer 23 and the p-side ohmic electrode 19.

According to the first embodiment, void portions 60 which are regions provided with no solder layer 23 are formed in the vicinity of the ends of the cavity facets 50 of the semiconductor element section 10 closer to the support substrate 30, as shown in FIG. 4. These void portions 60 which are the regions provided with no solder layer 23 are formed up to regions inwardly separated from the cavity facets 50 by an interval (L2) of about 25 μm, as shown in FIG. 3. Side end surfaces of the support substrate 30 are formed on positions inwardly deviating from the cavity facets 50 by a length (L3) of about 20 μm, by dicing in element division described later.

According to the first embodiment, the semiconductor element section 10 is so formed that the ratio of GaN is the largest so that the thermal expansion coefficient is close to the thermal expansion coefficient of GaN. Therefore, GaN has the largest thermal expansion coefficient of about 5.59×10⁻⁶ K⁻¹ in the [1-100] direction, and has the smallest thermal expansion coefficient of about 3.17×10⁻⁶ K⁻¹ in the [0001] direction in the plane of the (11-20) plane. Therefore, the semiconductor element section 10 is so formed as to have the largest thermal expansion coefficient in the vicinity of about 5.59×10⁻⁶ K⁻¹ in the [1-100] direction and to have the smallest thermal expansion coefficient in the vicinity of about 3.17×10⁻⁶ K⁻¹ in the [0001] direction in the in-plane directions of the first principal surface 10a and the second principal surface 10b substantially having the (11-20) planes.

According to the first embodiment, the support substrate 30 consists of n-type 6H—SiC doped with nitrogen.

Further, the support substrate 30 has a principal surface 30a having a (1-100) plane. In addition, the support substrate 30 has the largest thermal expansion coefficient of about 4.7×10⁻⁶ K⁻¹ in the [0001] direction and has the smallest thermal expansion coefficient of about 4.3×10⁻⁶ K⁻¹ in the [11-20] direction in the in-plane directions of the principal surface 30a having the (1-100) plane. The first principal surface 10a of the semiconductor element section 10 is bonded to the principal surface 30a of the support substrate 30 through the solder layer 23, so that the [0001] direction of the support substrate 30 coincides with the [1-100] direction of the semiconductor element section 10 and the [11-20] direction of the support substrate 30 substantially coincides with the [0001] direction of the semiconductor element section 10. The principal surface 30a is an example of the “second surface” in the present invention.

An n-side electrode 24 constituted of an n-side ohmic electrode, an n-side barrier metal and an n-side pad electrode successively from the side of the n-type contact layer 11 is formed on the back surface of the n-type contact layer 11 of the semiconductor element section 10, as shown in FIGS. 4 and 5. The n-side ohmic electrode constituting the n-side electrode 24 is made of Al, and the n-side barrier metal is made of Pt or Ti. The n-side barrier metal has a function of suppressing reaction between the n-side ohmic electrode and the n-side pad electrode.

According to the first embodiment, the submount 40 consists of a composite material of carbon and metal constituted by a graphite particle sintered body impregnated with Al. Further, the submount 40 is a rectangular parallelepiped having a thickness of about 300 μm, a length L4 of about 1200 μm and a width W3 of about 800 μm. In addition, the submount 40 is electrically conductive, and has a principal surface 40a. The longitudinal direction (direction along the long side) of the submount 40 is parallel to a direction along arrow E, and the cross direction (direction along the short side) is parallel to a direction along arrow F. The submount 40 is so worked that a plane perpendicular to the graphite crystal plane forms the principal surface 40a of the submount 40 while the direction along arrow E is perpendicular to the graphite crystal plane and the direction along arrow F is parallel to the graphite crystal plane. Therefore, the submount 40 has the largest thermal expansion coefficient of about 7×10⁻⁶ K⁻¹ in the direction (along arrow E) perpendicular to the graphite crystal plane, and has the smallest thermal expansion coefficient of about 4×10⁻⁶ K⁻¹ in the direction (along arrow F) parallel to the graphite crystal plane. The Young's modulus of this submount 40 is 6 GPa in the direction perpendicular to the graphite crystal plane, and 17 GPa in the direction parallel to the graphite crystal plane. Therefore, the submount 40 is so formed that the Young's modulus thereof is smaller than the Young's modulus of the semiconductor element section 10. To the principal surface 40a of the submount 40, the second principal surface 10b of the semiconductor element section 10 is bonded through a solder layer 70 so that the [1-100] direction of the semiconductor element section 10 coincides with the direction along arrow E and the [0001] direction of the semiconductor element section 10 substantially coincides with the direction along arrow F. For example, MIC30A by Toyo Tanso Co., Ltd. is used as the composite material of carbon and metal. The principal surface 40a is an example of the “second surface” in the present invention, and the solder layer 70 is an example of the “bonding layer” in the present invention.

According to the first embodiment, as hereinabove described, the semiconductor laser element is provided with the semiconductor element section 10 having the largest thermal expansion coefficient in the vicinity of about 5.59×10⁻⁶ K⁻¹ in the [1-100] direction and having the smallest thermal expansion coefficient in the vicinity of about 3.17×10⁻⁶ K⁻¹ in the [0001] direction in the in-plane directions of the second principal surface 10b having the (11-20) plane and the submount 40 having the largest thermal expansion coefficient of about 7×10⁻⁶ K⁻¹ in the direction along arrow E and the smallest thermal expansion coefficient of about 4×10⁻⁶ K⁻¹ in the direction along arrow F in the in-plane directions of the principal surface 40a and so formed as to bond the second principal surface 10b of the semiconductor element section 10 to the principal surface 40a of the submount 40 through the solder layer 70 so that the [1-100] direction of the semiconductor element section 10 coincides with the direction along arrow E and the [0001] direction of the semiconductor element section 10 substantially coincides with the direction along arrow F so that the direction of the second principal surface 10b of the semiconductor element section 10 having the largest thermal expansion coefficient and the direction of the principal surface 40a of the submount 40 having the largest thermal expansion coefficient can be coincided with each other, whereby the difference between the thermal expansion coefficients of the second principal surface 10b of the semiconductor element section 10 and the principal surface 40a of the submount 40 can be reduced. Thus, the second principal surface 10b of the semiconductor element section 10 can be inhibited from occurrence of strain resulting from the difference between a temperature for bonding the semiconductor element section 10 to the submount 40 and a temperature in operation of the semiconductor laser element. Consequently, degradation of the element characteristics of the semiconductor laser element can be suppressed. According to the first embodiment, further, the Young's modulus of the submount 40 is smaller than the Young's modulus of the semiconductor element section 10, whereby the second principal surface 10b of the semiconductor element section 10 can be further inhibited from occurrence of strain.

According to the first embodiment, the semiconductor laser element is provided with the support substrate 30 having the largest thermal expansion coefficient of about 4.7×10⁻⁶ K⁻¹ in the [0001] direction and having the smallest thermal expansion coefficient of about 4.3×10⁻⁶ K⁻¹ in the [11-20] direction in the in-plane directions of the principal surface 30a having the (1-100) plane and the semiconductor element section 10 having the largest thermal expansion coefficient in the vicinity of about 5.59×10⁻⁶ K⁻¹ in the [1-100] direction and having the smallest thermal expansion coefficient in the vicinity of about 3.17×10⁻⁶ K⁻¹ in the [0001] direction in the in-plane directions of the first principal surface 10a having the (11-20) plane and so formed as to bond the first principal surface 10a of the semiconductor element section 10 to the principal surface 30a of the support substrate 30 through the solder layer 23 so that the [1-100] direction of the semiconductor element section 10 coincides with the [0001] direction of the support substrate 30 and the [0001] direction of the semiconductor element section 10 substantially coincides with the [11-20] direction of the support substrate 30 so that the direction having the largest thermal expansion coefficient in the first principal surface 10a of the semiconductor element section 10 and the direction having the largest thermal expansion coefficient in the principal surface 30a of the support substrate 30 can be coincided with each other, whereby the difference between the thermal expansion coefficients of the first principal surface 10a of the semiconductor element section 10 and the principal surface 30a of the support substrate 30 can be reduced. Thus, the first principal surface 10a of the semiconductor element section 10 can be inhibited from occurrence of strain resulting from the difference between the temperature for bonding the semiconductor element section 10 to the support substrate 30 and the temperature in operation of the semiconductor laser element. Consequently, degradation of the element characteristics of the semiconductor laser element can be more suppressed.

According to the first embodiment, the difference between the thermal expansion coefficient in the [1-100] direction corresponding to the direction along the long side of the semiconductor element section 10 and the thermal expansion coefficient in the [0001] direction of the support substrate 30 is rendered smaller than the difference between the thermal expansion coefficient in the [0001] direction corresponding to the direction along the short side of the semiconductor element section 10 and the thermal expansion coefficient in the [11-20] direction of the support substrate 30, whereby the direction along the long side (longitudinal direction) of the semiconductor element section 10 easily causing strain as compared with the direction along the short side (cross direction) of the semiconductor element section 10 can be effectively inhibited from occurrence of strain.

According to the first embodiment, the semiconductor laser element is so formed as to have the void portions 60 which are the regions provided no solder layer 23 bonding the support substrate 30 and the semiconductor element section 10 to each other, whereby regions where the support substrate 30 and the semiconductor element section 10 are separated from each other can be formed in the vicinity of the ends of the cavity facets 50 of the semiconductor element section 10 closer to the support substrate 30 by the void portions 60 which are the regions provided with no solder layer 23. Thus, the semiconductor element section 10 can be cleaved without receiving influence by cleavability the support substrate 30, dissimilarly to a case where the solder layer 23 and the support substrate 30 are provided adjacently to the ends of the cavity facets 50 closer to the support substrate 30. Also when the (0001) plane of the support substrate 30 of 6H—SiC parallel to the cavity facets 50 has no cleavability, therefore, planarity of a cleavage plane of the semiconductor element section 10 can be improved.

According to the first embodiment, the support substrate 30 and the solder layer 23 are so formed as to have electric conductivity so that the principal surface 30a of the electrically conductive support substrate 30 and the first principal surface 10a of the semiconductor element section 10 can be bonded to each other through the electrically conductive solder layer 23, whereby the semiconductor element section 10 and the support substrate 30 can be electrically connected with each other.

According to the first embodiment, the semiconductor element section 10 is so formed as to be a semiconductor light-emitting element section including the emission layer 13 so that the semiconductor element section 10 is bonded to the support substrate 30 part and the submount 40 part respectively in the state inhibited from occurrence of strain on both of the first principal surface 10a and the second principal surface 10b, whereby degradation of the element characteristics of the light-emitting element section (semiconductor element section 10) can be easily suppressed.

A manufacturing process for the semiconductor laser element according to the first embodiment is described with reference to FIGS. 3 to 15. FIGS. 7 to 11 illustrate sectional views in the same direction as FIG. 5, and FIGS. 13 to 15 illustrate sectional views in the same direction as FIG. 4.

First, a mask 72 consisting of an SiO₂ film is formed on the upper surface of a GaN substrate 71 having a principal surface formed by a (11-20) plane misoriented (inclined) by 0.3° in the [000-1] direction, as shown in FIG. 7. This mask 72 is formed by ordinary lithography, to have openings 72a having a diameter of about 2 μm in a triangular lattice pattern in a cycle of intervals of about 10 μm. The GaN substrate 71 and the mask 72 constitute an underlayer for selective growth 73. The GaN substrate 71 is an example of the “growth substrate” in the present invention.

Then, the n-type contact layer 11 and the n-type cladding layer 12 are successively grown on the upper surface of the underlayer for selective growth 73 by metal organic vapor phase epitaxy (MOCVD) in a state holding the GaN substrate 71 at a growth temperature of about 1100° C. Then, the emission layer 13, the p-type optical guide layer 14 and the p-type cap layer 15 are successively grown on the upper surface of the n-type cladding layer 12 in a state holding the GaN substrate 71 at a growth temperature of about 800° C. Then, the p-type cladding layer 16 having the thickness of about 400 nm is grown on the upper surface of the p-type cap layer 15 in the state holding the GaN substrate 71 at the growth temperature of about 1100° C. Then, the p-type contact layer 17 is grown on the upper surface of the p-type cladding layer 17 in the state holding the GaN substrate 71 at the growth temperature of about 800° C. Thereafter annealing is performed in an N₂ atmosphere in a state holding the GaN substrate 71 at a growth temperature of about 900° C., thereby activating acceptors in the p-type nitride semiconductor layers and obtaining a prescribed hole concentration.

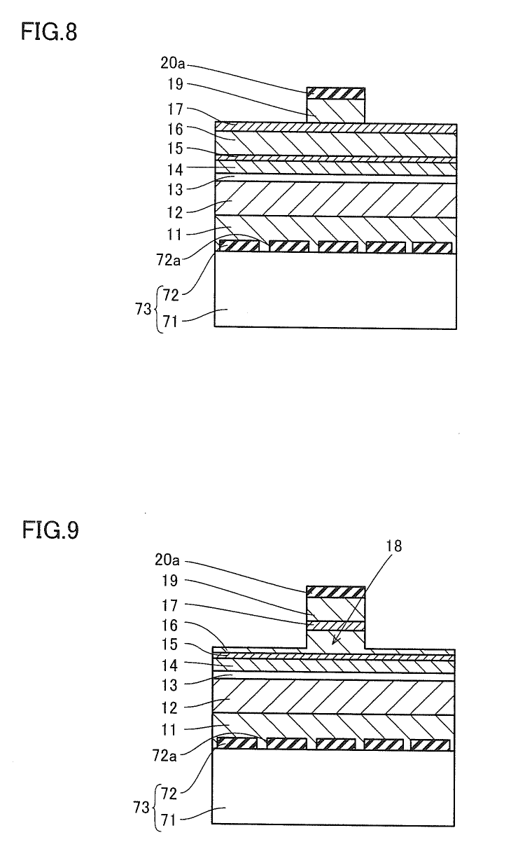

Then, the p-side ohmic electrode 19 and an insulating film 20a of SiO₂ having a thickness of about 0.25 μm are successively formed on the upper surface of the p-type contact layer 17 by vacuum evaporation or the like and thereafter patterned, thereby obtaining the p-side ohmic electrode 19 and the insulating film 20a having shapes shown in FIG. 8. The p-side ohmic electrode 19 is formed by stacking the Pt layer having the thickness of about 5 μm, the Pd layer having the thickness of about 100 μm and the Au layer having the thickness of about 150 nm from the side of the p-type contact layer 17.

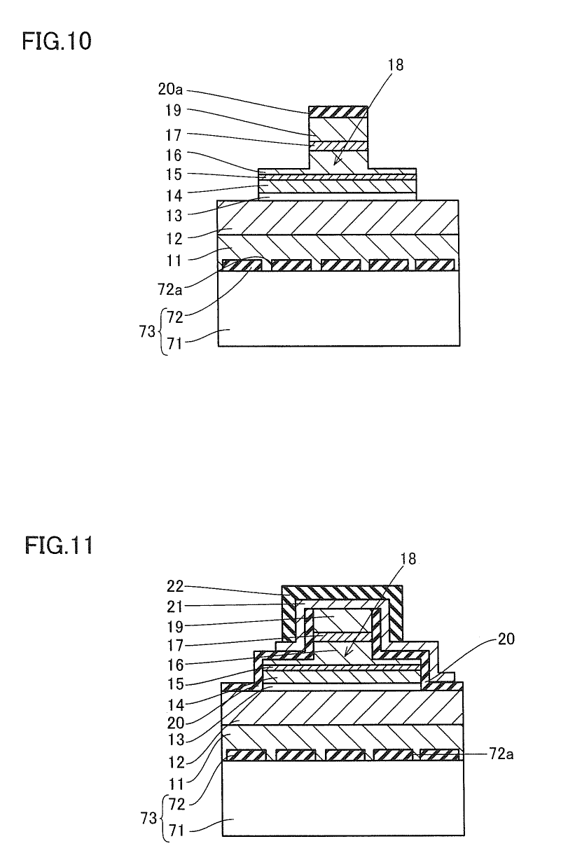

Then, dry etching with a Cl₂-based gas is performed through a mask of the insulating film 20a for partially removing the p-type contact layer 17 and the p-type cladding layer 16 thereby forming the ridge portion 18 extending in the [1-100] direction, as shown in FIG. 9. The width of this ridge portion 18 is about 1.5 μm, and the height of the ridge portion 18 of about 380 nm. Then, the emission layer 13, the p-type optical guide layer 14, the p-type cap layer 15 and the planar portion of the p-type cladding layer 16 are partially etched by photolithography and dry etching, thereby patterning the emission layer 13, the p-type optical guide layer 14, the p-type cap layer 15 and the p-type cladding layer 16 to have a width of about 4.5 μm, as shown in FIG. 10.

Then, the insulating film 20 of SiN having the thickness of about 250 nm is formed to cover the upper surface of the n-type cladding layer 12, the side surface of the emission layer 13, the side surface of the p-type optical guide layer 14, the side surface of the p-type cap layer 15, the side surface of the planar portion of the p-type cladding layer 16, the upper surface of the planar portion of the p-type cladding layer 16, the side surface of the ridge portion 18 and the upper surface of the insulating film 20a, and only the portions of the insulating films 20 and 20a located on the p-side ohmic electrode 19 are removed, as shown in FIG. 11. Then, the p-side pad electrode 21 consisting of the Ti layer having the thickness of about 100 nm, the Pd layer having the thickness of about 100 nm and the Au layer having the thickness of about 3 μm from the lower layer toward the upper layer is formed on the upper surfaces of the p-side ohmic electrode 19 and the insulating film 20. Thereafter the insulating film 22 of SiO₂ having the thickness of about 100 nm is formed on the upper surface of the p-side pad electrode 21.

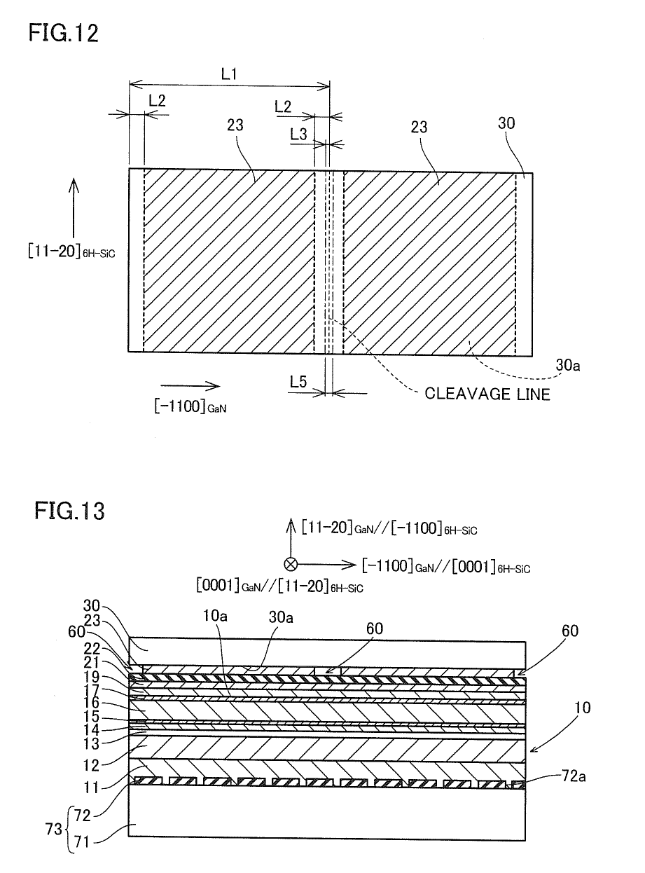

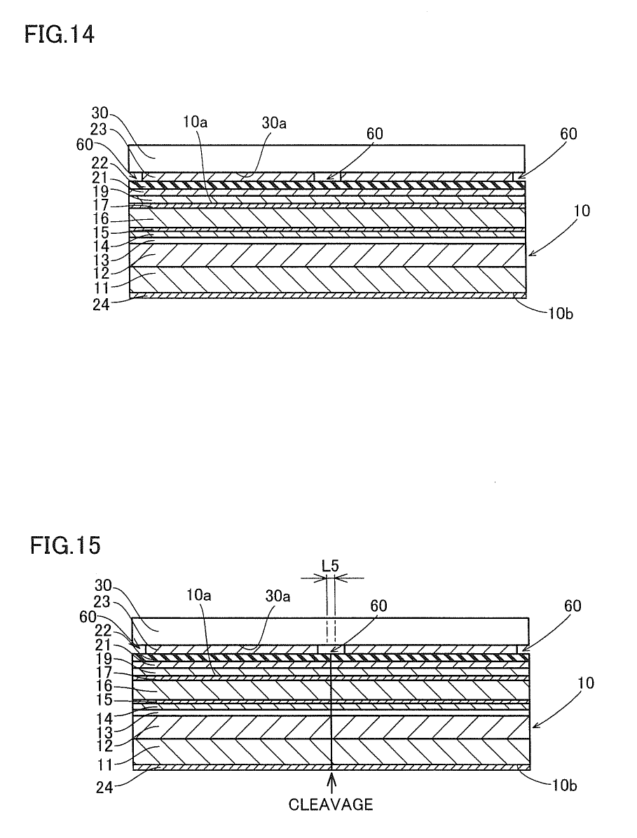

According to the first embodiment, the solder layer 23 is previously patterned in the form of stripes extending in the [11-20] direction on the principal surface 30a of the support substrate 30, as shown in FIG. 12. The semiconductor element section 10 is adhered to the support substrate 30 so that the striped pattern of the solder layer 23 extending in the [11-20] direction of the support substrate 30 and the ridge portion 18 extending in the [1-100] direction of the semiconductor element section 10 are orthogonal to each other. Thus, the first principal surface 10a of the semiconductor element section 10 is bonded to the principal surface 30a of the support substrate 30 through the solder layer 23, so that the direction of the support substrate 30 coincides with the [1-100] direction of the semiconductor element section 10 and the [11-20] direction of the support substrate 30 substantially coincides with the [0001] direction of the semiconductor element section 10. Further, the semiconductor element section 10 and the support substrate 30 are so bonded to each other that the void portions 60 which are the regions provided with no solder layer 23 are present in bonding (welding), as shown in FIG. 13. Thereafter the underlayer for selective growth 73 is removed by dry etching for exposing the overall surface of the opposite side of the n-type contact layer 11 to the support substrate 30, whereby the shape shown in FIG. 14 is obtained.

While alignment in the adhesion between the support substrate 30 and the semiconductor element section 10 is performed through the solder layer 23 patterned on the support substrate 30 in the striped manner and the ridge portion 18 of the semiconductor element section 10 in the first embodiment, orientation flats may be formed on the support substrate 30 and the underlayer for selective growth 73, and alignment in the adhesion may be so performed that the orientation flats coincides with each other. More specifically, alignment in the adhesion may be so performed that the (1-100) plane of the underlayer for selective growth 73 and the (0001) plane of the support substrate 30 coincide with each other by forming an orientation flat of the (1-100) plane on the underlayer for selective growth 73 and forming an orientation flat of the (0001) plane on the support substrate 30.

Thereafter the n-side ohmic electrode, the n-side barrier metal and the n-side pad electrode are successively formed on the back surface of the n-type contact layer 11 from the side of the n-type contact layer 11, thereby forming the n-side electrode 24.

As shown in FIGS. 12 and 15, a scribing groove (not shown) is provided on the surface of the semiconductor element section 10 perpendicular to the principal surface 30a of the support substrate 30, for performing cleavage on the (1-100) plane of the semiconductor element section 10 with ultrasonic waves.

According to the first embodiment, cleavage of the semiconductor element section 10 is performed along the cleavage plane of the semiconductor element section 10 on the positions of the void portions 60 which are the regions provided with no solder layer 23 in the vicinity of an end of the support substrate 30 side of the area where the cleavage plane is supposed to be formed.

Thereafter only the support substrate 30 is diced with a width (L5) of about 40 μm, thereby dividing the semiconductor element section 10.

Thereafter the second principal surface 10b of the semiconductor element 10 is bonded to the upper surface of the principal surface 40a of the submount 40 through the solder layer 70, so that the direction along the long side (along arrow E) of the submount 40 and the extensional direction (cavity direction) of the ridge portion 18 of the semiconductor element section 10 coincide with each other. Thus, the second principal surface 10b of the semiconductor element section 10 is bonded to the principal surface 40a of the submount 40 through the solder layer 70, so that the [1-100] direction of the semiconductor element section 10 coincides with the direction along arrow E and the [0001] direction of the semiconductor element section 10 substantially coincides with the direction along arrow F. Thus, the semiconductor laser element according to the first embodiment shown in FIGS. 3 to 5 is formed.

### Second Embodiment

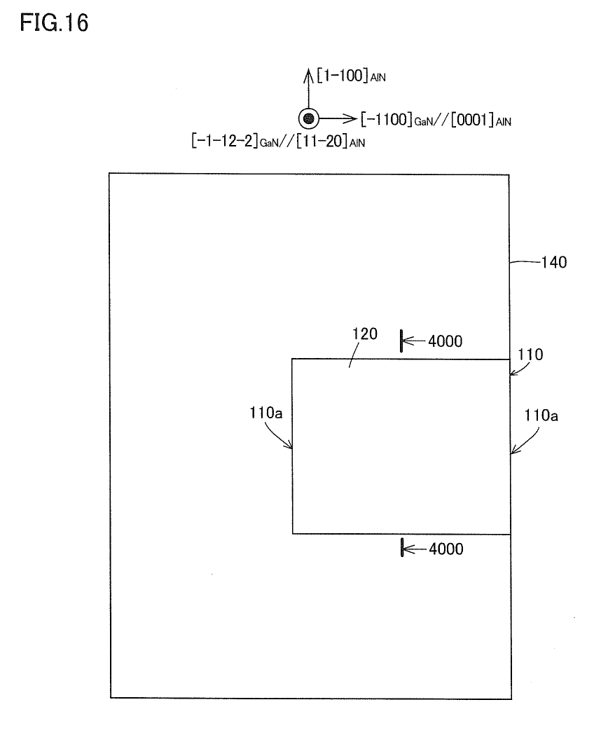

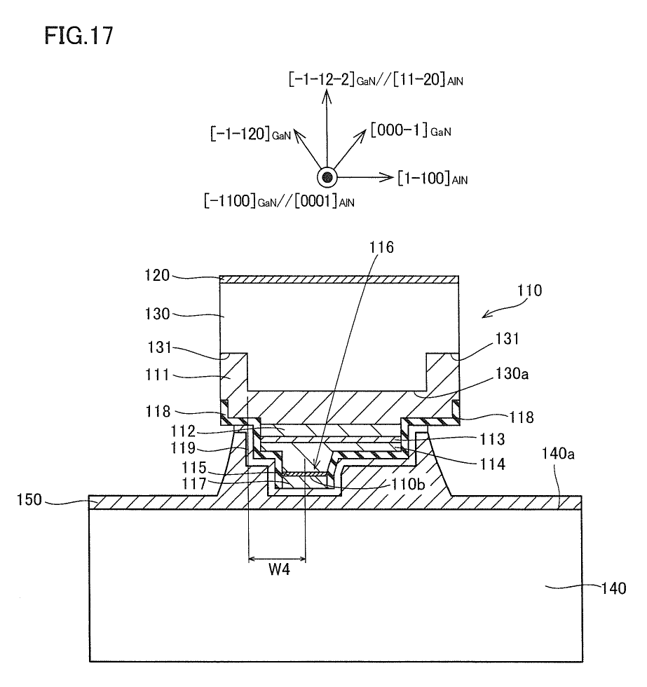

In this second embodiment, a GaN-based semiconductor laser element having a structure employing no support substrate dissimilarly to the aforementioned first embodiment is described with reference to FIGS. 16 and 17. The second embodiment is described with reference to the case of applying the present invention to the GaN-based semiconductor laser element which is an exemplary semiconductor element. The oscillation wavelength of the GaN-based semiconductor laser element according to the second embodiment is about 410 nm.

The GaN-based semiconductor laser element according to the second embodiment comprises a semiconductor element section 110 and a submount 140, as shown in FIGS. 16 and 17. The submount 140 is an example of the “base” in the present invention.

The semiconductor element section 110 includes an n-type GaN substrate 130 having a thickness of about 100 μm and consisting of n-type GaN doped with Si. The n-type GaN substrate 130 has a principal surface 130a having a (11-22) plane. Steps 131 extending in the [1-100] direction and having a depth of about 0.5 μm and a width of about 20 μm are formed on both side ends of the n-type GaN substrate 130.

An n-type cladding layer 111 having a thickness of about 400 nm and consisting of n-type Al_{0.07}Ga_{0.93}N doped with Si is formed on the surface of the n-type GaN substrate 130 closer to the submount 140. An active layer 112 is formed on the surface of the n-type cladding layer 111 closer to the submount 140. This active layer 112 has an MQW structure in which four barrier layers having a thickness of about 20 nm and consisting of undoped In_{0.02}Ga_{0.98}N and three well layers having a thickness of about 3 nm and consisting of undoped In_{0.15}Ga_{0.85}N are alternately stacked. The active layer 112 is an example of the “emission layer” in the present invention.

A p-type cap layer 113 having a thickness of about 20 nm and consisting of Al_{0.16}Ga_{0.84}N doped with Mg is formed on the surface of the active layer 112 closer to the submount 140. A p-type cladding layer 114 having a projecting portion and a planar portion other than the projecting portion and consisting of p-type Al_{0.07}Ga_{0.93}N doped with Mg is formed on the surface of the p-type cap layer 113 closer to the submount 140. The thickness of the planar portion of this p-type cladding layer 114 is about 10 nm, and the thickness of the projecting portion is about 330 nm. The projecting portion of the p-type cladding layer 114 has a width of about 1.75 μm, and is formed at an interval of about 50 μm (W4 in FIG. 17) toward the center side from the side surface of one step portion 131 of the n-type GaN substrate 130.

A p-type contact layer 115 having a thickness of about 80 nm and consisting of In_{0.02}Ga_{0.98}N doped with Mg is formed on the upper surface of the projecting portion of the p-type cladding layer 114. This p-type contact layer 115 and the projecting portion of the p-type cladding layer 114 constitute a ridge portion 116. This ridge portion 116 is so formed as to extend in the [1-100] direction.

A p-side ohmic electrode 117 constituted of a Pt layer having a thickness of about 5 nm, a Pd layer having a thickness of about 100 nm and an Au layer having a thickness of about 150 nm from the side opposite to the submount 140 toward the submount 140 is formed on the surface of the p-type contact layer 115 constituting the ridge portion 116 closer to the submount 140. A current narrowing layer 118 consisting of an SiO₂ film (insulating film) having a thickness of about 250 nm is formed on the surface of the region of the p-side ohmic electrode 117 other than the surface closer to the submount 140. A p-side pad electrode 119 consisting of a Ti layer having a thickness of about 100 nm, a Pd layer having a thickness of about 100 nm and an Au layer having a thickness of about 3 μm from the side opposite to the submount 140 toward the submount 140 is formed on a prescribed region of the surface of the current narrowing layer 118, to be in contact with the surface of the p-type ohmic electrode 117 closer to the submount 140.

An n-side electrode 120 constituted of an n-side ohmic electrode, an n-side barrier metal and an n-side pad electrode is formed on the surface of the opposite side of the n-type GaN substrate 130 to the submount 140.

In the semiconductor element section 110, cavity facets 110a consisting of cleavage planes of (1-100) and (−1100) planes are formed on both ends of the ridge portion 116 extending in the [1-100] direction.

According to the second embodiment, the semiconductor element section 110 is so formed as to have the largest thermal expansion coefficient in the vicinity of about 5.59×10⁻⁶ K⁻¹ in the [1-100] direction corresponding to the direction along the long side and have the smallest thermal expansion coefficient in the vicinity of about 4×10⁻⁶ K⁻¹ in the direction, corresponding to the direction along the short side, perpendicular to the [1-100] direction in the in-plane directions of a principal surface (overall surface of the semiconductor element section 110 closer to the p-type contact layer 115) 110b having the (11-22) plane. The principal surface 110b is an example of the “first surface” in the present invention.

According to the second embodiment, the submount 140 has electric conductivity, and is made of single-crystalline AlN having the (11-20) plane as a principal surface 140a. The submount 140 is a rectangular parallelepiped having a thickness of about 300 μm, a length of about 1200 μm and a width of about 800 μm. The longitudinal direction (direction along the long side) of the submount 140 is parallel to the [1-100] direction, and the cross direction (direction along the short side) is parallel to the [0001] direction. The submount 140 has the smallest thermal expansion coefficient of about 4.2×10⁻⁶ K⁻¹ in the [1-100] direction and has the largest thermal expansion coefficient of about 5.3×10⁻⁶ K⁻¹ in the [0001] direction in the in-plane directions of the principal surface 140a. To the principal surface 140a of the submount 140, the principal surface 110b of the semiconductor element 110 closer to the ridge portion 116 is bonded in a junction-down configuration through a solder layer 150 of AuSn or the like, so that the cross direction (direction along the short side) of the submount 140 and the extensional direction (cavity direction) of the ridge portion 116 of the semiconductor element section 110 coincide with each other. Thus, the principal surface 110b of the semiconductor element section 110 is bonded to the principal surface 140a of the submount 140 through the solder layer 150, so that the [1-100] direction of the semiconductor element section 110 coincides with the direction of the submount 140. The principal surface 140a is an example of the “second surface” in the present invention, and the solder layer 150 is an example of the “bonding layer” in the present invention.

According to the second embodiment, as hereinabove described, the semiconductor laser element is provided with the semiconductor element section 110 having the largest thermal expansion coefficient in the vicinity of about 5.59×10⁻⁶ K⁻¹ in the [1-100] direction and having the smallest thermal expansion coefficient in the vicinity of about 4×10⁻⁶ K⁻¹ in the direction perpendicular to the [1-100] direction in the in-plane directions of the principal surface 110b having the (11-22) plane and the submount 140 having the smallest thermal expansion coefficient of about 4.2×10⁻⁶ K⁻¹ in the [1-100] direction and having the largest thermal expansion coefficient of about 5.3×10⁻⁶ K⁻¹ in the [0001] direction in the in-plane directions of the principal surface 140a having the (11-20) plane and so formed as to bond the principal surface 110b of the semiconductor element section 110 to the principal surface 140a of the submount 140 through the solder layer 150 so that the [1-100] direction of the semiconductor element section 110 having the largest thermal expansion coefficient coincides with the [0001] direction of the submount 140 having the largest thermal expansion coefficient so that the direction having the largest thermal expansion coefficient in the principal surface 110b of the semiconductor element section 110 and the direction having the largest thermal expansion coefficient in the principal surface 140a of the submount 140 having the largest thermal expansion coefficient can be coincided with each other, whereby the difference between the thermal expansion coefficients in the principal surface 110b of the semiconductor element section 110 and the principal surface 140a of the submount 140 can be reduced. Thus, the principal surface 110b of the semiconductor element section 110 can be inhibited from occurrence of strain resulting from the difference between a temperature for bonding the semiconductor element section 110 to the submount 140 and a temperature in operation of the GaN-based semiconductor laser element. Consequently, degradation of element characteristics of the GaN-based semiconductor laser element can be suppressed.

According to the second embodiment, the steps 131 extending in the [1-100] direction are so formed on both side ends of the n-type GaN substrate 130 that the n-type cladding layer 111 can be laterally grown, whereby the n-type cladding layer 111 of AlGaN can be inhibited from causing strain and easily forming cracks due to the fact that the lattice constant of the n-type cladding layer 111 of AlGaN is small as compared with the lattice constant of the n-type GaN substrate 130.

The remaining effects of the second embodiment are similar to those of the aforementioned first embodiment.

### Third Embodiment

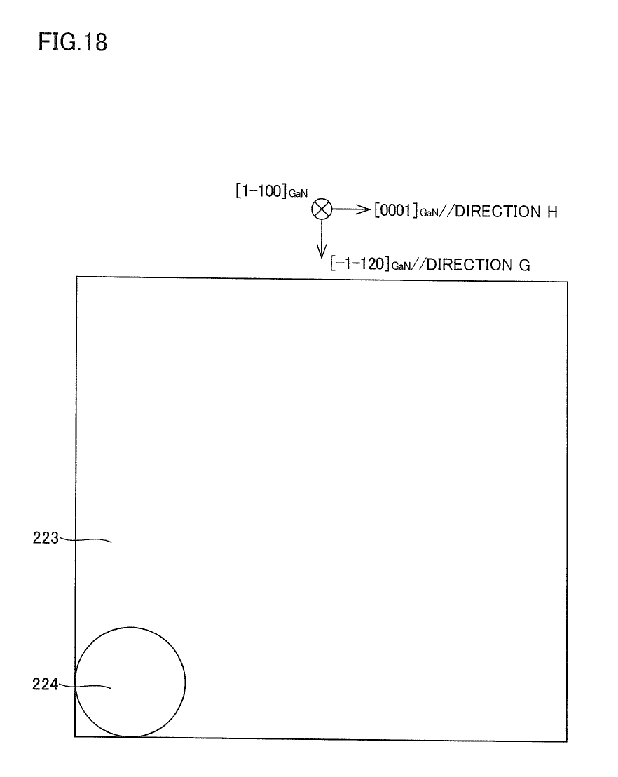

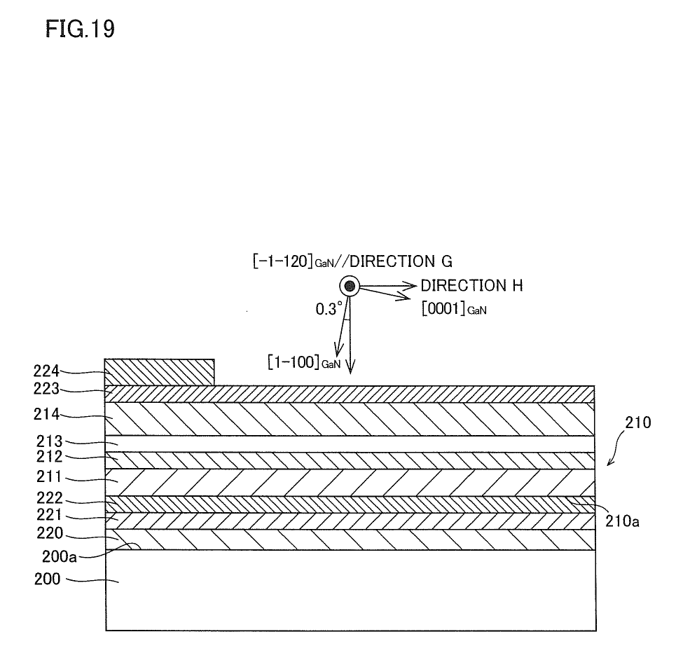

The structure of an LED element according to a third embodiment is described with reference to FIGS. 18 and 19. The third embodiment is described with reference to the case of applying the present invention to the LED element which is an exemplary semiconductor element. The peak wavelength of the light-emitting diode element according to the third embodiment is about 480 nm.

The LED device according to the third embodiment comprises a support substrate 200 and an LED element section 210, as shown in FIGS. 18 and 19. The support substrate 200 is an example of the “base” in the present invention, and the LED element section 210 is an example of the “semiconductor element section” in the present invention.

The support substrate 200 has a thickness of about 300 μm, and is in the form of a square having a length of about 400 μm on each side in plan view. The support substrate 200 consists of a composite material of carbon and metal constituted of a graphite particle sintered body impregnated with Al. Further, the support substrate 200 has electric conductivity. The support substrate 200 is so worked that a plane perpendicular to the graphite crystal plane forms a principal surface 200a of the support substrate 200 while a direction along arrow G is perpendicular to the graphite crystal plane and a direction along arrow H is parallel to the graphite crystal plane. Therefore, the support substrate 200 has the largest thermal expansion coefficient of about 7×10⁻⁶ K⁻¹ in the direction (along arrow G) perpendicular to the graphite crystal plane and has the smallest thermal expansion coefficient of about 4×10⁻⁶ K⁻¹ in the direction (along arrow H) parallel to the graphite crystal plane in the in-plane directions of the principal surface 200a. For example, MIC30A by Toyo Tanso Co., Ltd. is used as the composite material of carbon and metal. The principal surface 200a is an example of the “second surface” in the present invention.

A electrically conductive solder layer 220 of AuSn having a thickness of about 3 μm is formed on the upper surface of the principal surface 200a of the support substrate 200. A p-side pad electrode 221 and a p-side ohmic electrode 222 are formed on the upper surface of the solder layer 220. The solder layer 220 is an example of the “bonding layer” in the present invention.

According to the third embodiment, the LED element section 210 consists of an nitride-based semiconductor having a wurtzite structure. This LED element section 210 has a principal surface 210a substantially having a (1-100) plane misoriented (inclined) by about 0.3° in the [000-1] direction. The LED element section 210 has the largest thermal expansion coefficient in the vicinity of about 5.59×10⁻⁶ K⁻¹ in the [11-20] direction and has the smallest thermal expansion coefficient in the vicinity of about 3.17×10⁻⁶ K⁻¹ in the [0001] direction in the in-plane directions of the principal surface 210a having the (1-100) plane. To the principal surface 200a of the support substrate 200, the principal surface 210a of the LED element section 210 is bonded through the solder layer 220 so that the direction (along arrow G) of the support substrate 200 perpendicular to the graphite crystal plane coincides with the [11-20] direction of the LED element section 210 and the direction (along arrow H) of the support substrate 200 parallel to the graphite crystal plane coincides with the [0001] direction of the LED element section 210. The principal surface 210a is an example of the “first surface” in the present invention.

A p-type contact layer 211 having a thickness of about 100 nm and consisting of GaN doped with Mg is formed on the upper surface of the p-side ohmic electrode 222. A cap layer 212 having a thickness of about 20 nm and consisting of Al_{0.05}Ga_{0.95}N doped with Mg is formed on the upper surface of the p-type contact layer 211. A single quantum well emission layer 213 having a thickness of about 3 nm and consisting of In_{0.25}Ga_{0.75}N doped with Si is formed on the upper surface of the cap layer 212. An n-type contact layer 214 having a thickness of about 3 μm and consisting of GaN doped with Si is formed on the upper surface of the single quantum well emission layer 213.

An n-side light-transmitting ohmic electrode 223 is formed on the upper surface of the n-type contact layer 214. An n-side pad electrode 224 having a diameter of about 125 μm is formed on a prescribed region of the upper surface of the n-side light-transmitting ohmic electrode 223.

The effects of the third embodiment are similar to those of the aforementioned first embodiment.

### Fourth Embodiment

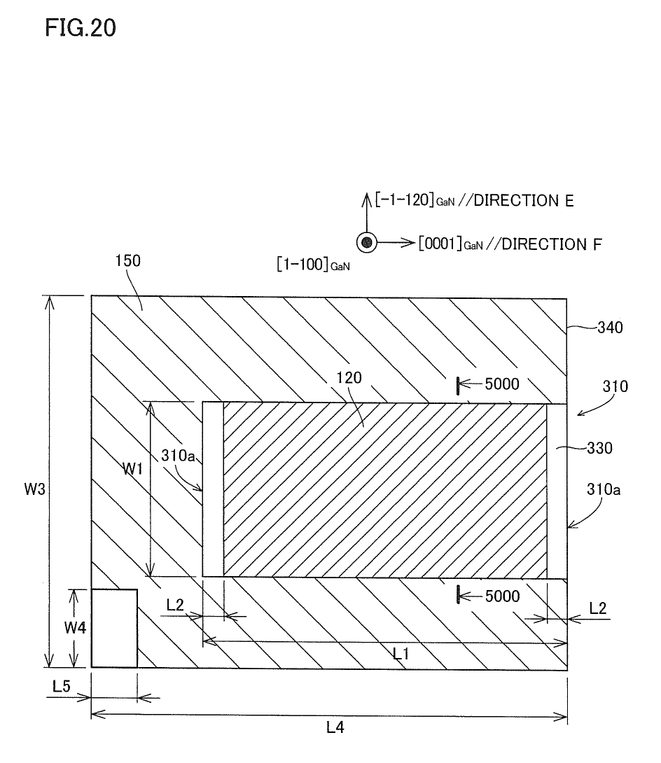

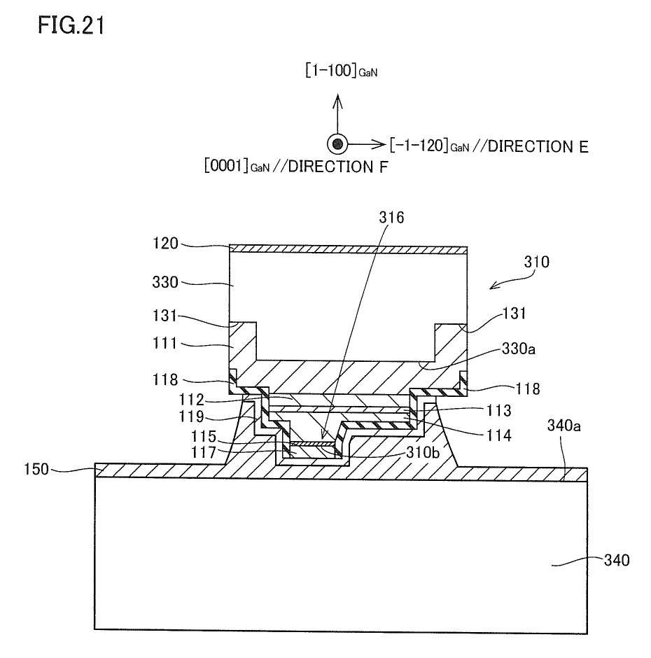

In this fourth embodiment, a GaN-based semiconductor laser element having a structure employing no support substrate dissimilarly to the aforementioned first embodiment is described with reference to FIGS. 20 and 21. The fourth embodiment is described with reference to the case of applying the present invention to the GaN-based semiconductor laser element which is an exemplary semiconductor element. The oscillation wavelength of the GaN-based semiconductor laser element according to the fourth embodiment is about 410 nm.

The GaN-based semiconductor laser element according to the fourth embodiment comprises a semiconductor element section 310 and a submount 340, as shown in FIGS. 20 and 21. The submount 340 is an example of the “base” in the present invention.

The semiconductor element section 310 includes an n-type GaN substrate 330 having a thickness of about 100 μm and consisting of n-type GaN doped with Si. The n-type GaN substrate 330 has a principal surface 330a having a (1-100) plane. A ridge portion 316 is so formed as to extend in the [0001] direction. In the semiconductor element section 310, cavity facets 310a consisting of cleavage planes of (0001) and (000-1) planes are formed on both ends of the ridge portion 316 extending in the [0001] direction. The length (cavity length) L1 of the semiconductor element section 310 is about 900 μm, and the width W1 is about 200 μm. The remaining structure of the semiconductor element section 310 is similar to that of the aforementioned second embodiment.

According to the fourth embodiment, the semiconductor element section 310 is so formed as to have the largest thermal expansion coefficient in the vicinity of about 5.59×10⁻⁶ K⁻¹ in the [−1-120] direction corresponding to the direction along the short side and have the smallest thermal expansion coefficient in the vicinity of about 3.17×10⁻⁶ K⁻¹ in the [0001] direction corresponding to the direction along the long side in the in-plane directions of a principal surface 310b having the (1-100) plane. The principal surface 310b is the “first surface” in the present invention.

According to the fourth embodiment, an n-side electrode 120 is formed on a portion of the back surface of the n-type GaN substrate 330 excluding portions of a length L2 of about 10 μm from the cavity facets 310a. In other words, the back surface of the n-type GaN substrate 330 has a rectangular shape and the n-side electrode 120 is not formed in the vicinity of the cavity facets 310a, whereby the appearance of the semiconductor element section 310 is so formed that the direction having the largest thermal expansion coefficient and the direction having the smallest thermal expansion coefficient can be distinguished from each other in the plane of the principal surface 310b. The remaining structure of the semiconductor element section 310 is similar to that of the aforementioned second embodiment.

According to the fourth embodiment, the submount 340 consists of a composite material of carbon and metal constituted of a graphite particle sintered body impregnated with Al. The submount 340 is a rectangular parallelepiped having a thickness of about 300 μm, a length L4 of about 1200 μm and a width W3 of about 800 μm. The direction along the long side of the submount 340 is parallel to a direction along arrow F, and the direction along the short side is parallel to a direction along arrow E. The submount 340 is so worked that a plane perpendicular to the graphite crystal plane forms the principal surface 340a of the submount 340 while the direction along arrow E is perpendicular to the graphite crystal plane and the direction along arrow F is parallel to the graphite crystal plane. Therefore, the submount 340 has the largest thermal expansion coefficient of about 7×10⁻⁶ K⁻¹ in the direction (along arrow E) perpendicular to the graphite crystal plane and has the smallest thermal expansion coefficient of about 4×10⁻⁶ K⁻¹ in the direction (along arrow F) parallel to the graphite crystal plane in the in-plane directions of the principal surface 340a.

According to the fourth embodiment, a solder layer 150 of AuSn or the like of AuSn or the like is formed on the principal surface 340a of the submount 340. A rectangular notch having a width w4 of about 200 μm and a length L5 of about 50 μm is formed on the solder layer 150. In other words, the shape of the principal surface 340a of the submount 340 is rectangular and the rectangular notch is formed on the solder layer 150, whereby the appearance of the submount 340 is so formed that the direction having the largest thermal expansion coefficient and the direction having the smallest thermal expansion coefficient can be distinguished from each other in the plane of the principal surface 340a.

According to the fourth embodiment, the principal surface 310b of the semiconductor element section 310 closer to the ridge portion 316 is bonded to the principal surface 340a of the submount 340 in a junction-down configuration through the solder layer 150, so that the direction along the short side of the submount 340 and the extensional direction (cavity direction) of the ridge portion 316 of the semiconductor element section 310 coincide with each other. Thus, the principal surface 310b of the semiconductor element section 310 is bonded to the principal surface 340a of the submount 340 through the solder layer 150, so that the [0001] direction of the semiconductor element section 310 coincides with the direction F of the submount 340. The principal surface 340a is an example of the “second surface” in the present invention, and the solder layer 150 is an example of the “bonding layer” in the present invention.

According to the fourth embodiment, as hereinabove described, the semiconductor laser element is provided with the semiconductor element section 310 having the largest thermal expansion coefficient in the vicinity of about 5.59×10⁻⁶ K⁻¹ in the [−1-120] direction and having the smallest thermal expansion coefficient in the vicinity of about 3.17×10⁻⁶ K⁻¹ in the [0001] direction and the submount 340 having the smallest thermal expansion coefficient in the vicinity of about 3.17×10⁻⁶ K⁻¹ in the direction F and having the largest thermal expansion coefficient of about 7×10⁻⁶ K⁻¹ in the direction E and so formed as to bond the principal surface 310b of the semiconductor element section 310 to the principal surface 340a of the submount 340 through the solder layer 150 so that the [0001] direction of the semiconductor element section 310 having the smallest thermal expansion coefficient coincides with the direction F of the submount 340 having the smallest thermal expansion coefficient so that the direction having the smallest thermal expansion coefficient in the principal surface 310b of the semiconductor element section 310 and the direction having the smallest thermal expansion coefficient in the principal surface 340a of the submount 340 can be coincided with each other, whereby the difference between the thermal expansion coefficients in the principal surface 310b of the semiconductor element section 310 and the principal surface 340a of the submount 340 can be reduced.

According to the fourth embodiment, the difference between the thermal expansion coefficient in the [0001] direction corresponding to the direction along the long side of the semiconductor element section 310 and the thermal expansion coefficient of the submount 340 in the direction F is rendered smaller than the difference between the thermal expansion coefficient in the [−1-120] direction corresponding to the direction along the short side of the semiconductor element section 310 and the thermal expansion coefficient of the submount 340 in the direction E, whereby the direction along the long side (longitudinal direction) easily causing strain as compared with the direction along the short side (cross direction) of the semiconductor element section 310 can be effectively inhibited from occurrence of strain.

The remaining effects of the fourth embodiment are similar to those of the aforementioned first embodiment.

The embodiments disclosed this time must be considered as illustrative in all points and not restrictive. The range of the present invention is shown not by the above description of the embodiments but by the scope of claims for patent, and all modifications within the meaning and range equivalent to the scope of claims for patent are included.

For example, the examples of applying the present invention to the semiconductor laser elements and the light-emitting diode element have been shown in the aforementioned first to fourth embodiments, the present invention is not restricted to this but is also applicable to still another semiconductor element.

While the examples employing the nitride-based semiconductors as the materials for the semiconductor element sections and the LED element section have been shown in the aforementioned first to fourth embodiments, the present invention is not restricted to this but semiconductors such as ZnO having wurtzite structures may be employed as the materials for the semiconductor element sections and the LED element section.

While the examples of employing SiC, the composite material of carbon and metal etc. as the materials having thermal expansion coefficients varying with the in-plane directions have been shown in the aforementioned first to fourth embodiments, the present invention is not restricted to this but a material having an orthorhombic, tetragonal or hexagonal crystal structure thereby having thermal expansion coefficients varying with the in-plane directions may be employed.

While the example of employing the (11-20) plane or the (1-100) plane as the principal surface has been shown in each of the aforementioned first to fourth embodiments, the present invention is not restricted to this but a (H, K, −H−K, 0) plane may be employed as the principal surface, or a plane misoriented by about several degrees from the (H, K, −H−K, 0) plane may be employed.

While the example of employing the solder layer of AuSn or the like as the bonding layer has been shown in each of the aforementioned first to fourth embodiments, the present invention is not restricted to this but a solder layer made of a material other than AuSn may be employed as the bonding layer. For example, solder of InSn, SnAgCu, SnAgBi, SnAgCuBi, SnAgBiIn, SnZn, SnCu, SnBi or SnZnBi may be employed as the bonding layer. Further, a material such as electrically conductive paste may be employed as the bonding layer.

1. A semiconductor element comprising:
a semiconductor element section having a first surface and including a plurality of directions having different thermal expansion coefficients in the in-plane directions of said first surface; and
a base having a second surface and including a plurality of directions having different thermal expansion coefficients in the in-plane directions of said second surface, with said first surface of said semiconductor element section bonded to said second surface, wherein
said semiconductor element section is so bonded to said base that the direction having the largest thermal expansion coefficient in the first surface of said semiconductor element section is closer to the side of the direction having the largest thermal expansion coefficient than the direction having the smallest thermal expansion coefficient in the second surface of said base.

2. The semiconductor element according to claim 1, wherein
the direction having the largest thermal expansion coefficient in the in-plane directions of the first surface of said semiconductor element section substantially coincides with the direction having the largest thermal expansion coefficient in the in-plane directions of the second surface of said base.

3. The semiconductor element according to claim 1, wherein
when the largest thermal expansion coefficient and the smallest thermal expansion coefficient in the in-plane directions of the first surface of said semiconductor element section are α_{EL} and α_{ES} respectively, and
the largest thermal expansion coefficient and the smallest thermal expansion coefficient in the in-plane directions of the second surface of said base are α_{SL} and α_{SS} respectively,
at least one relation of α_{SL}≧α_{EL}>α_{SS} or α_{SL}>α_{ES}≧α_{SS} or α_{EL}≧_{SL}>α_{ES} or α_{EL}>α_{SS}≧α_{ES} holds between the thermal expansion coefficients in the respective directions of said base and said semiconductor element section.

4. The semiconductor element according to claim 1, wherein
when the largest thermal expansion coefficient and the smallest thermal expansion coefficient in the in-plane directions of the first surface of said semiconductor element section are α_{EL} and α_{ES} respectively, and
the largest thermal expansion coefficient and the smallest thermal expansion coefficient in the in-plane directions of the second surface of said base are α_{SL} and α_{SS} respectively,
the relation of α_{SL}>α_{SS}≧α_{EL}>α_{ES} or α_{EL}>α_{ES}≧α_{sL}>α_{SS} holds between the thermal expansion coefficients in the respective directions of said base and said semiconductor element section.

5. The semiconductor element according to claim 1, wherein
when the largest thermal expansion coefficient and the smallest thermal expansion coefficient in the first surface of said semiconductor element section are α_{EL} and α_{ES} respectively, and
the largest thermal expansion coefficient and the smallest thermal expansion coefficient in the second surface of said base are α_{SL} and α_{SS} respectively,
the first surface of said semiconductor element section is rectangularly formed so that the thermal expansion coefficient in the direction along the long side is α_{ES} if |α_{SL}−α_{EL}>|α_{SS}−α_{ES}|, and
the first surface of said semiconductor element section is rectangularly formed so that the thermal expansion coefficient in the direction along the long side is α_{EL} if |α_{SL}−α_{EL}|<|α_{SS}−α_{ES}|.

6. The semiconductor element according to claim 1, wherein
the appearance of said semiconductor element section is so formed that the direction having the largest thermal expansion coefficient in the in-plane directions of the first surface of said semiconductor element section and the direction having the smallest thermal expansion coefficient in the in-plane directions of the first surface of said semiconductor element section can be distinguished from each other.

7. The semiconductor element according to claim 1, wherein
the shape of said first surface of said semiconductor element section is substantially rectangularly formed.

8. The semiconductor element according to claim 1, wherein
the appearance of said semiconductor element section is so formed that the direction having the largest thermal expansion coefficient in the in-plane directions of the second surface of said base and the direction having the smallest thermal expansion coefficient in the in-plane directions of the second surface of said base can be distinguished from each other.

9. The semiconductor element according to claim 1, wherein
said semiconductor element section includes a semiconductor layer having said first surface and having a hexagonal structure or a wurtzite structure, and
said first surface is substantially a (H, K, −H−K, 0) plane, where at least either one of H and K is a nonzero integer.

10. The semiconductor element according to claim 1, further comprising a bonding layer for bonding the second surface of said base and the first surface of said semiconductor element section to each other.

11. The semiconductor element according to claim 10, wherein
said base and said bonding layer are both electrically conductive.

12. The semiconductor element according to claim 10, wherein
said bonding layer is provided on a region separated from a cavity facet of said semiconductor element section at a prescribed distance in the extensional direction of a cavity.

13. The semiconductor element according to claim 1, so formed that the Young's modulus of said base is smaller than the Young's modulus of said semiconductor element section.

14. The semiconductor element according to claim 1, wherein
said semiconductor element section is a semiconductor light-emitting element section including an emission layer.

15. The semiconductor element according to claim 1, wherein
said base is a submount.

16. A method for manufacturing a semiconductor element, comprising steps of:
forming a semiconductor element section having a first surface and including a plurality of directions having different thermal expansion coefficients in the in-plane directions of said first surface;
bonding said first surface of said semiconductor element section to a second surface of a base having said second surface and including a plurality of directions having different thermal expansion coefficients in the in-plane directions of said second surface so that the direction having the largest thermal expansion coefficient in said first surface is closer to the side of the direction having the largest thermal expansion coefficient than the direction having the smallest thermal expansion coefficient in said second surface.

17. The method for manufacturing a semiconductor element according to claim 16, wherein
the step of forming said semiconductor element section includes a step of growing said semiconductor element section including the plurality of directions having the different thermal expansion coefficients in the in-plane directions of said first surface on the surface of a growth substrate including a plurality of directions having different thermal expansion coefficients in the in-plane directions.

18. The method for manufacturing a semiconductor element according to claim 16, wherein
the step of bonding said first surface of said semiconductor element section to said second surface of said base includes a step of bonding a side of said semiconductor element section formed on a growth substrate in the step of forming said semiconductor element section to said base to be opposed thereto,
the method further comprises a step of removing said growth substrate after the step of bonding said first surface of said semiconductor element section to said second surface of said base, and
said base is a support substrate.

19. The method for manufacturing a semiconductor element according to claim 16, wherein
when the largest thermal expansion coefficient and the smallest thermal expansion coefficient in the first surface of said semiconductor element section are α_{EL} and α_{ES} respectively, and
the largest thermal expansion coefficient and the smallest thermal expansion coefficient in the second surface of said base are α_{SL} and α_{SS} respectively,
the step of forming said semiconductor element section having said first surface includes a step of:
rectangularly forming the first surface of said semiconductor element section so that the thermal expansion coefficient in the direction along the long side is α_{ES} if |α_{SL}−α_{EL}|>|α_{SS}−α_{ES}|, and
rectangularly forming the first surface of said semiconductor element section so that the thermal expansion coefficient in the direction along the long side is α_{EL} if |α_{EL}−α_{EL}<|α_{SS}−α_{ES}|.

20. The method for manufacturing a semiconductor element according to claim 16, wherein
when the largest thermal expansion coefficient and the smallest thermal expansion coefficient in the first surface of said semiconductor element section are α_{EL} and α_{ES} respectively, and
the largest thermal expansion coefficient and the smallest thermal expansion coefficient in the second surface of said base are α_{SL} and α_{SS} respectively,
the step of bonding the first surface of said semiconductor element section to said second surface of said base includes a step of bonding the surfaces to each other while coinciding the in-plane directions of the second surface of said base and the in-plane directions of the first surface of said semiconductor element section with each other so that at least one relation of α_{SL}≧α_{EL}>α_{SS} or α_{SL}>α_{ES}≧α_{SS} or α_{EL}≧α_{SL}>α_{ES} or α_{EL}>α_{SS}≧α_{ES} holds between the thermal expansion coefficients in the respective directions of said base and said semiconductor element section.
